(19) United States
(12) Patent Application Publication
(10) Pub. No.: US 2010/0218812 A1
(43) Pub. Date: Sep. 2, 2010

(54) PHOTOVOLTAICS

(76) Inventors: Julie Baker, Leavesden (GB); Nicholas J. Dartnell, Cambridgeshire (GB)

Correspondence Address: EASTMAN KODAK COMPANY;PATENT LEGAL STAFF, 343 STATE STREET, ROCHESTER, NY, 14650-2201, US

(21) Appl. No.: 12/682,790

(22) PCT Filed: Oct. 7, 2008
(86) PCT No.: PCT/GB2008/003384

§ 371 Date: Apr. 13, 2010

(30) Foreign Application Priority Data
Oct. 19, 2007 (GB) 0720515.6

(51) Int. Cl. H01L 31/0232; H01L 31/18

(52) U.S. Cl. 136/252; 438/69; 257/E31.127

(57) ABSTRACT

A photovoltaic device comprises an anode having a film of semi conductive particles deposited and sintered on a substrate, an electrolyte and a cathode. The electrolyte includes light scattering particles.

### FIELD OF THE INVENTION

This invention relates generally to photovoltaics, in particular to the use of light scattering particles in the electrolyte in dye sensitised solar cells to improve fill factor and therefore overall performance.

### BACKGROUND OF THE INVENTION

Conventional dye-sensitized solar cells as described by Gratzel consist of a transparent conducting substrate such as ITO on glass, on top of which is a sintered layer of dye coated titanium dioxide nanoparticles (the anode). A hole carrying electrolyte which typically contains iodide/tri-iodide as the electron (or hole) transfer agent is placed within the pores of and on top of this layer. The solar cell sandwich is completed by putting on top of the electrolyte a catalytic conducting electrode, often made with platinum as the catalyst (the cathode). When light is shone on the cell, the dye is excited and an electron is injected into the titanium structure. The excited, now positively charged dye oxidises the reduced form of the redox couple in the electrolyte to its oxidised form e.g. iodide goes to tri-iodide. This may now diffuse towards the platinum electrode. When the cell is connected to a load the electrons from the anode pass through the load to the cathode and at the cathode the oxidised form of the redox couple is reduced e.g. tri-iodide to iodide, completing the reaction.

Often a light scattering layer is incorporated into the structure of the dye sensitised solar cell to ensure that as much light is absorbed as possible.

Conventional methods of increasing light scatter within a dye sensitised solar cell often involve the use of an additional layer deposited on top of the nanoporous titanium dioxide anode. This layer either contains a mixture of TiO₂ particle sizes where one is the same as those used in the lower layer and the other is significantly larger, or in other cases, the extra layer only contains the much larger particles, with the aim to increase light scatter within the cell and improve overall cell efficiency. An alternative approach is to use the mixture of particle sizes in both layers, but use more of the larger particles in the second layer. Use of these layers requires an additional process step to deposit it on top of the standard nanoporous layer.

US2006/0197170 discloses a dye sensitised solar cell where the light absorbing layer contains light scattering particles which are different in size from the light absorbing particles. The light scattering particles that are different in size (specifically larger) from the light absorbing particles cause incident light to be adequately scattered, increasing the optical path through the light absorbing layer, enhancing light absorption. As a result, the conversion efficiency and output of the cell are improved. The light scattering particles may be made of the same material as the light absorbing particles (e.g. titanium dioxide, tin dioxide, zinc oxide, tungsten oxide or niobium oxide to name a few) or may be made from a different material. In this application, the light scattering particles are preferably 20 nm or less while the light scattering particles are between 20 and 100 nm in diameter.

EP 1271580A1 describes a metal oxide semiconductor layer (preferably TiO₂) where two particle sizes are mixed resulting in improved photon conversion efficiency by improving light scattering. Preferably a two-layer structure is used. The first layer is less porous than the second layer (achieved by using a lower level of the larger particles in the first layer) and provides a larger surface for dye absorption. The role of the second layer is to increase the light scattering effect because of the presence of the larger metal oxide particles.

US 2002/0134426 also discloses a multilayer structure where performance can be enhanced by controlling the haze ratio of the layers by differentiating the particle diameters used. The first layer comprises particles of smaller and uniform size to suppress light scatter while the second layer is used to scatter the light. It is preferred that the particles used in the second layer have a particle diameter of four times or more that of the particles used in the first layer.

### PROBLEM TO BE SOLVED BY THE INVENTION

Conventional methods of increasing light scatter within a dye sensitised solar cell often involve the use of an additional layer deposited on top of the nanoporous titanium dioxide anode. Use of such layers requires an additional process step to deposit it on top of the standard nanoporous layer.

### SUMMARY OF THE INVENTION

According to the present invention there is provided a photovoltaic device comprising an anode having a film of semi conductive particles deposited and sintered on a substrate, an electrolyte and a cathode, the electrolyte including light scattering particles.

### ADVANTAGEOUS EFFECT OF THE INVENTION

By incorporating the light scattering particles into the liquid electrolyte the extra process step during manufacturing is removed. This simplifies the production process.

The light scattering effect is still achieved whilst simplifying the manufacturing process.

The invention allows lower cost solar cells to be manufactured.

### BRIEF DESCRIPTION OF THE DRAWINGS

The invention will now be described with reference to the accompanying drawing in which:

FIG. 1 is a graph illustrating the effect of adding light scattering particles to the electrolyte on cell performance.

### DETAILED DESCRIPTION OF THE INVENTION

Each aspect of the present invention will now be discussed.

A working electrode includes, for example, a substrate and a conductive layer, upon which a layer of dye sensitised porous film of oxide semiconductor fine particles is deposited.

Examples of the substrate include, but are not limited to, a plastic, a glass, a metal, a ceramic, or the like.

Plastics that may be used as the substrate include, for example, polyethylene terephthalate (PET), polyethylene naphthalate (PEN), polybutylene terephthalate (PBT), a polyimide, and the like. Glasses that may be used as the substrate include, for example, borosilicate glass, quartz glass, soda glass, and the like. Metals that may be used as the substrate include, for example, titanium, nickel, and the like. Preferably, the substrate will be a plastic.

A conductive layer is deposited on the substrate, which will be made of a conductive metal oxide, such as indium doped tin oxide (ITO) if a plastic substrate is to be used. In the case of a glass, metal or ceramic substrate, a layer of fluorine doped tin oxide may be used. It is preferable that the conductive layer is substantially transparent.

The material constituting the substrate and the conductive layer must be resistant to the electrolyte. In the case in which an electrolyte containing iodine is used, copper and silver are unsuitable materials, for example, as they are readily attacked by the iodine and easily dissolve into the electrolyte.

The method used to form the conductive layer on the chosen support is not particularly limited and examples include any known film formation methods, such as sputtering methods, or CVD methods, or spray decomposition methods.

The oxide semiconductive porous film is a porous thin layer containing particles of a metal oxide. Metal oxide particles that may be used include titanium oxide (TiO₂), tin oxide (SnO₂), tungsten oxide (WO₃), zinc oxide (ZnO), niobium oxide (Nb₂O₅) and antimony oxide (Sb₂O₅). Preferably, the metal oxide particles will be titanium oxide (TiO₂).

The method for forming the oxide semiconductive porous film is not particularly limited. It can be formed, for example, by employing methods in which a dispersion solution that is obtained by dispersing commercially available oxide semiconductor fine particles in a desired dispersion medium, or a colloid solution that can be prepared using a sol-gel method is applied, after desired additives have been added if required, using a known coating method such as a screen printing method, an inkjet method, a roll coating method, a doctor blade method, a spin coating method, a spray coating method, or the like. Sintering of the oxide semiconductive porous film may be achieved via pressure or heat, depending on the substrate chosen.

The dye that is provided in the oxide semiconductive porous film is not particularly limited, and it is possible to use ruthenium complexes or iron complexes containing bipyridine structures, terpyridine structures, and the like in a ligand; metal complexes such as porphyrin and phthalocyanine; as well as organic dyes such as, but not limited to, eosin, rhodamine, coumarin and melocyanine, or derivatives of the above. The dye can be selected according to the application and the semiconductor that is used for the oxide semiconductive porous film. Preferably, the dye will be a ruthenium complex.

For the electrolyte solution, it is possible to use, for example, a ‘polymer gel electrolyte’, an organic solvent electrolyte or an ionic liquid based electrolyte (room temperature molten salt) that in each case contain a redox pair.

The electrolyte is composed of a redox pair contained in a liquid solvent or a pseudo solid form (that permits ionic conduction or charge transport). The solvent for the liquid electrolyte can be a purely organic solvent or a so called ionic liquid (room temperature molten) of low volatility, or a combination of these components, and in turn the redox pair can contain a component that is considered a molten salt. The pseudo solid electrolyte can be considered by means of adding gelling agents to a liquid form of the electrolyte, for example by the use of polymers such as epichlorohydrin-co-ethylene oxide or poly(vinylidene fluoride-co-hexafluoropropylene) (PVDF-HFP), or sugars such as sorbitol derivatives or the addition of nanoparticles such as silica or other solids, e.g. Lithium salts. Alternatively it can be created through the addition of the redox pair to a system that is essentially solid in certain areas of its phase diagram such as plastic crystals like succinonitrile. The polymer gelled electrolyte may in addition contain plasticisers such as for example propylene and/or ethylene carbonate. In addition, light scattering particles are added to the electrolyte which should be larger than those used in the anode. The light scattering particles should be larger than 30 nm. Preferably they are larger than 100 nm. Most preferably they are larger than 150 nm.

The light scattering particles may be of the same material as those used to create the anode but may also be of a different material. Suitable materials include titanium dioxide, tin dioxide, zinc oxide, tungsten oxide or niobium oxide. This list is not to be taken as exhaustive

Examples of the organic solvent include acetonitrile, methoxy acetonitrile, propionitrile, propylene carbonate and diethyl carbonate.

Examples of the ionic liquid include salts made of cations, such as quaternary imidazolium based cations and anions, iodide ions or bistrifluoromethyl sulfonylimido anions, dicyanoamide anions, and the like.

The redox pair that is contained in the electrolyte is not particularly limited. For example, combinations such as iodine with iodide ions or bromine with bromide ions may be used to create the redox pair.

Additives such as tert-butylpyridine and the like may also be added to the electrolyte.

The method for forming the electrolyte layer between the working electrode and the counter electrode includes for example, a method in which the electrodes are disposed facing each other and the electrolyte is supplied between the electrodes to form the electrolyte layer. Alternatively, the electrolyte may be dropped, applied or cast onto the working electrode or counter electrode to form the electrolyte layer and the other electrode may then be stacked on top. In order to prevent leakage of the electrolyte from the space between the working electrode and the counter electrode, it is preferable to seal the gap between the electrodes with an appropriate material.

The counter electrode includes an electron conductive material. This could be a conductive substrate or an electron conductive material (for example ITO or FTO) coated on an electron insulating support and a catalytic coating. The conductive substrate could include a conductive transparent substrate or a metal substrate but the invention is not limited to these substrates. The counter electrode acts as a catalyst for the regeneration of the redox pair in the cell. Specific examples of the catalytic coating include platinum and carbon, or combinations thereof.

Described below is an example of the invention;

### Example

The device is referred to as a dye sensitized solar cell. This wording should not be seen as limiting to the invention.

Titanium dioxide was dried in an oven at 90° C. overnight prior to use. This was a titanium dioxide sample which had an average particle size of 21 nm (Degussa Aeroxide P25, specific surface area (BET)=50+/−15 m²/g).

Two samples of 13 Ω/square ITO-PEN were taken and approximately 30 μm thick mesoporous TiO₂ films were deposited onto each, dispersing the dried TiO₂ in a mixture of dry Methyl Ethyl Ketone and Ethyl Acetate in the following amounts for each sample:

| | |
|---|---|
| Degussa P25 TiO₂ (21 nm particles) | 1.35 g |
| Methyl Ethyl Ketone | 45 g |
| Ethyl Acetate | 5 g |

Each resulting mixture was sonicated for 15 minutes before being sprayed onto the conducting plastic substrate from a distance of approximately 25 cm using a SATAminijet 3 HVLP spray gun with a 1 mm nozzle and 2 bar nitrogen carrier gas. The layer was allowed to dry in an oven at 90° C. for one hour, before being placed between two sheets of Teflon, sandwiched between two polished stainless steel bolsters and compressed with a pressure of 15 tonnes for 15 seconds. The sintered layer was then allowed to dry for a further hour at 90° C.

Each sample was then sensitised by placing them in a 3×10⁻⁴ mol dm⁻³ solution of ruthenium cis-bis-isothiocyanato bis(2,2′bipyridyl-4,4′dicarboxylic acid) overnight.

Platinum coated stainless steel foil counter electrodes were prepared by sputter deposition under vacuum.

The dye sensitised TiO₂ layers and the platinum counter electrode were arranged in a sandwich type configuration with an ionic liquid electrolyte in between. For cell A (the control) a standard electrolyte was used which comprised:

### 0.1M LiI

0.6M DMPII (1,2dimethyl-3-propyl-imidazolium iodide)

### 0.05M I₂

### 0.5M N-methylbenzimidazole

### Solvent=MPN (Methoxypropionitrile)

For cell B (the invention), some larger titanium dioxide particles (Kemira AFDC, average particle size of 170 nm, specific surface area (BET)=10 m²/g) were added to the electrolyte prior to filling the cell. The particles were added at a rate of 250 g/litre of electrolyte.

Following fabrication, the dye sensitised solar cells were characterised by placing under a source that artificially replicated the solar spectrum in the visible region to provide illumination levels approximating to 0.10 sun, 0.50 sun and 0.88 sun.

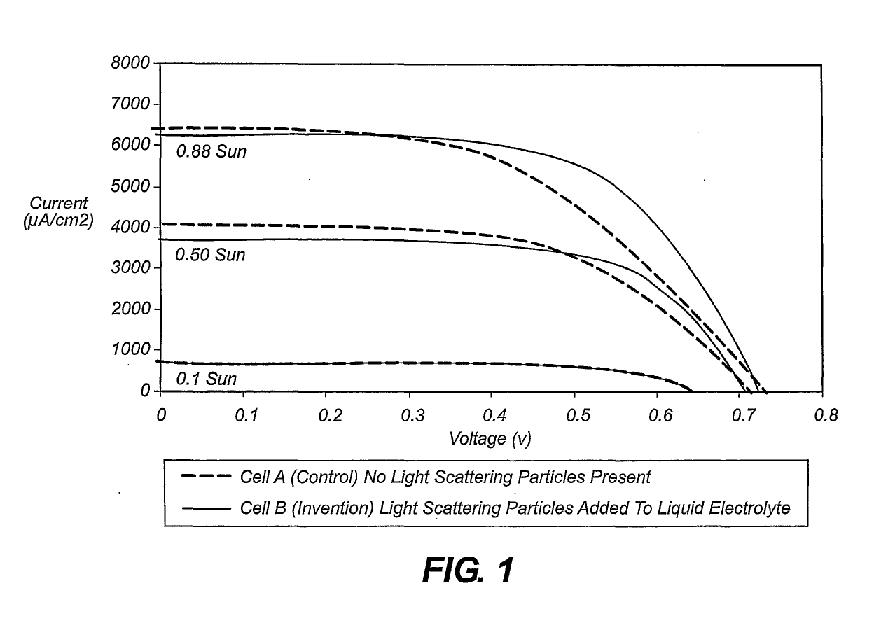

The data in FIG. 1 demonstrate the increase in fill factor that is achieved when light scattering particles were added to the electrolyte. As expected, this results in an overall improvement in cell efficiency at all illumination levels, as shown in Table 1.

TABLE 1
The effect of adding light scattering particles to the electrolyte on cell performance

| | Light Scattering | | | | | |
|---|---|---|---|---|---|---|
| | Particles In | Illumination | % | Isc | Voc | Fill |
| Cell | Electrolyte | (Suns) | Efficiency | (mA/cm²) | (v) | Factor |
| A (Control) | No | 0.10 | 3.02 | 0.701 | 0.645 | 0.670 |
| | No | 0.50 | 3.33 | 4.042 | 0.716 | 0.578 |
| | No | 0.88 | 2.68 | 6.450 | 0.732 | 0.504 |
| B (Invention) | Yes | 0.10 | 3.06 | 0.695 | 0.640 | 0.689 |
| | Yes | 0.50 | 3.44 | 3.706 | 0.708 | 0.664 |
| | Yes | 0.88 | 3.19 | 6.276 | 0.724 | 0.625 |

This example demonstrates that enhanced cell performance can be achieved by adding light scattering particles to the electrolyte. Light scattering improvements are usually achieved by using a multi-layer approach resulting in a more complex manufacturing process. By adding the light scattering particles to the ionic liquid electrolyte, the step involving depositing the layer containing the light scattering particles is eliminated, simplifying the process.

As illustrated in the above example the scattering particles should be larger than those used in the anode. The light scattering particles should be larger than 30 nm. Preferably they are larger than 100 nm. Most preferably they are larger than 150 nm.

The above example describes light scattering particles of the same material as those used to create the anode. This however is not necessary for the invention to work. The light scattering particles may be of a different material. Suitable materials include titanium dioxide, tin dioxide, zinc oxide, tungsten oxide or niobium oxide. This list is not to be taken as exhaustive.

The electrolyte used may be a liquid or polymer based electrolyte.

The rate of addition of the particles to the electrolyte is not critical to the invention. Lower rates than 250 g/litre can be used.

The invention has been described in detail with reference to preferred embodiments thereof. It will be understood by those skilled in the art that variations and modifications can be effected within the scope of the invention.

1. A photovoltaic device comprising an anode having a film of semi conductive particles deposited and sintered on a substrate, an electrolyte and a cathode, the electrolyte including light scattering particles.

2. A device as claimed in claim 1 wherein the light scattering particles are larger than the particles comprising the anode.

3. A device as claimed in claim 1 wherein the light scattering particles are larger than 30 nm.

4. A device as claimed in claim 3 wherein the light scattering particles are larger than 100 nm.

5. A device as claimed in claim 4 wherein the light scattering particles are larger than 150 nm.

6. A device as claimed in claim 1 wherein the anode is dye sensitised.

7. A device as claimed in claim 1 wherein the light scattering particles are of the same material as those used to create the anode.

8. A device as claimed in claim 1 wherein the light scattering particles are titanium dioxide.

9. A method of forming a photovoltaic device comprising creating an anode having a film of semiconductive particles deposited and sintered on a substrate, an electrolyte and a cathode, wherein the electrolyte includes light scattering particles.
